(19) United States
(12) Patent Application Publication
(10) Pub. No.: US 2008/0164604 A1
(43) Pub. Date: Jul. 10, 2008

(54) Heat dissipating semiconductor package

(75) Inventors: Liang-Yi Hung, Taichung (TW); Yu-Po Wang, Taichung Hsien (TW); Cheng-Hsu Hsiao, Taichung Hsien (TW)

Correspondence Address: Edwards Angell,;Palmer & Dodge LLP, P.O. Box 55874, Boston, MA, 02205, US

(73) Assignee: Siliconware Precision Industries Co., Ltd., Taichung (TW)

(21) Appl. No.: 12/008,202

(22) Filed: Jan. 8, 2008

(30) Foreign Application Priority Data
Jan. 10, 2007 (TW) 096100878

(51) Int. Cl. H01L 23/34

(52) U.S. Cl. 257/717; 257/E23.101

(57) ABSTRACT

A heat dissipating semiconductor package is disclosed, including a chip carrier; at least a semiconductor chip mounted and electrically connected to the chip carrier; and a heat dissipating member mounted on the semiconductor chip with a thermal interface material (TIM) interposed therebetween, wherein the TIM is provided with a plurality of fillers for supporting the TIM at an appropriate height, thereby preventing the TIM from being wetted so as to avoid collapsing and overflow of the TIM as a result of wetting problem.

### BACKGROUND OF THE INVENTION

1. Field of the Invention

The present invention relates generally to a semiconductor package, and more particularly to a heat dissipating semiconductor package.

2. Description of Related Art

In a flip chip ball grid array (FCBGA) semiconductor package, an active surface of a semiconductor chip is electrically connected with one surface of the substrate through a plurality of conductive bumps and a plurality of solder balls functioning as I/O ports is mounted to the other opposite surface of the substrate. As such a package structure greatly reduces package size, avoids conventional bonding wire design, reduces resistance, improves electrical performance and prevents signal fading in signal transmission process, it has become a mainstream package technique for next generation chips and electronic components and is particularly applied in high integration electronic components so as to meet size and operation requirements thereof. However, due to high frequency operation characteristic of the high integration electronic components, much more heat is generated by the high integration electronic components during operation. As a result, how to obtain a good heat dissipating effect has become critical in such a semiconductor package design.

For a conventional FCBGA semiconductor package, a heat dissipating member is directly mounted to a non-active surface of the semiconductor chip for improving heat dissipation compared with other semiconductor packages.

Material used for mounting is generally an epoxy base material with a thermal conductivity of 2˜4 w/m° K. Compared with a heat dissipating member having a thermal conductivity of several hundreds of w/m° K, for example a heat dissipating member made of copper having a thermal conductivity of 400 w/m° K, the epoxy base material having such a low thermal conductivity cannot efficiently transfer heat. Therefore, materials having high thermal conductivity should be used for connection between the heat dissipating member and the semiconductor chip so as to improve heat transferring efficiency.

U.S. Pat. No. 6,504,242, No. 6,380,621, and No. 6,504,723 use a Sn-base solder material as a thermal interface material (TIM) between the heat dissipating member and the flip-chip semiconductor chip. The Sn-base solder material has a thermal conductivity of 50 w/m° K. Particularly if pure tin is used, the thermal conductivity of the material can reach 86 w/m° K. Compared with the conventional epoxy-base material, the Sn-base solder material is much more capable of meeting the demand for high heat dissipating efficiency.

However, as shown in FIG. 1, the TIM made of the solder material 15 has a good wetting ability with the heat dissipating member 13 generally made of copper. Once they are melted by heat and combined, the solder material 15 can quickly diffuse on the heat dissipating member 13. Thus, the solder material 15 lacks an enough thickness, which limits solder bonding from being formed between heat dissipating member 13 and the flip-chip semiconductor chip 12. Meanwhile, the connecting area between the solder material 15 and the flip-chip semiconductor chip 12 is reduced, and even a disconnecting problem can occur, thus adversely affecting the heat dissipating efficiency and product reliability.

FIG. 2 is a sectional diagram of a heat dissipating semiconductor package disclosed by U.S. Pat. No. 6,380,621. As shown in FIG. 2, metallic layers 24 made of such as Ni or Au is pre-formed on non-active surface of the flip-chip semiconductor chip 22 and surface of the heat dissipating member 23 such that when the TIM made of a solder material 25 is melted for mounting, solder bonding can be formed between the solder material 25 and the metallic layers 24, thus limiting the wetting area. However, during mounting the heat dissipating member, the solder material is at a liquid state, the solder material can easily overflow to the substrate surface and accordingly causes the electricity bridge problem of the passive components on the substrate surface.

FIGS. 3A and 3B are sectional diagrams of a heat dissipating semiconductor package disclosed by U.S. Pat. No. 6,504,723. As shown in FIGS. 3A and 3B, a heat dissipating structure 33 having a protruding portion 331 located at central position thereof and extending portions 332 located at periphery thereof is provided, wherein surface of the protruding portion 331 is pre-coated with a soldering flux 36. The extending portions 332 of the heat dissipating structure 33 are mounted to the substrate 31 through a bonding material 37 and the protruding portion 331 of the heat dissipating structure 33 is mounted to the solder material 35 pre-disposed on the non-active surface of the flip-chip semiconductor chip 32. Meanwhile, the solder material 35 is melted by heat so as to diffuse to the gaps between the protruding portion 331 of the heat dissipating structure 33 and the flip-chip semiconductor chip 32, wherein the flow of the solder material 35 is limited by oblique surfaces of the protruding portion 331.

However, such a heat dissipating structure is over-complicated and its fabrication cost is high. As a result, application of the heat dissipating structure is limited.

Therefore, there is a need to provide a heat dissipating structure to overcome the above problems.

### SUMMARY OF THE INVENTION

According to the above drawbacks, an objective of the present invention is to provide a heat dissipating semiconductor package, through which wetting area of the TIM between the heat dissipating member and the semiconductor chip can be limited.

Another objective of the present invention is to provide a heat dissipating semiconductor package, which can ensure the TIM has an enough thickness so as to form solder bonding between the heat dissipating member and the semiconductor chip.

A further objective of the present invention is to provide a heat dissipating semiconductor package without using a complicated heat dissipating structure, thereby reducing the fabrication complexity, saving fabrication and cost.

In order to attain the above and other objectives, the present invention discloses a heat dissipating semiconductor package, which comprises: a chip carrier; at least a semiconductor chip mounted and electrically connected to the chip carrier; and a heat dissipating member mounted on the semiconductor chip with a thermal interface material (TIM) interposed therebetween, wherein the TIM is provided with a plurality of fillers for supporting the TIM at an appropriate height.

The TIM is a solder material, and the fillers are made of a material having high melting point and good thermal conductivity, such as copper, aluminum or alloy thereof or diamond.

The chip carrier may be such as a substrate, and the semiconductor chip is mounted on the substrate by flip chip technique. The heat dissipating member may be made of such as copper.

Therefore, according to the present invention, inside a TIM used for connecting a heat dissipating member to a semiconductor chip, there is disposed a plurality of fillers such that when the TIM is melted by heat, the fillers can control the TIM at an appropriate height so as to prevent over-wetting of the TIM and thus prevent collapsing or overflow of the TIM caused by the over-wetting problem. Further, the fillers can support the TIM to obtain an enough thickness such that an solder bonding can be formed between the heat dissipating member and the non-active surface of the flip-chip semiconductor chip, thereby ensuring an efficient bonding between the heat dissipating member and the flip-chip semiconductor chip. Meanwhile, compared with the complicated heat dissipating structure of the prior art, the present invention simplifies the fabrication process and saves fabrication time and cost.

### BRIEF DESCRIPTION OF DRAWINGS

FIG. 1 is a diagram showing a conventional diffusing problem occurring when a heat dissipating member is mounted to a semiconductor chip with a solder TIM interposed therebetween;

FIG. 2 is a sectional diagram of a heat dissipating semiconductor package disclosed by U.S. Pat. No. 6,380,621;

FIGS. 3A and 3B are sectional diagrams showing a heat dissipating semiconductor package disclosed by U.S. Pat. No. 6,504,723; and

FIG. 4 is a sectional diagram of a heat dissipating semiconductor package according to the present invention.

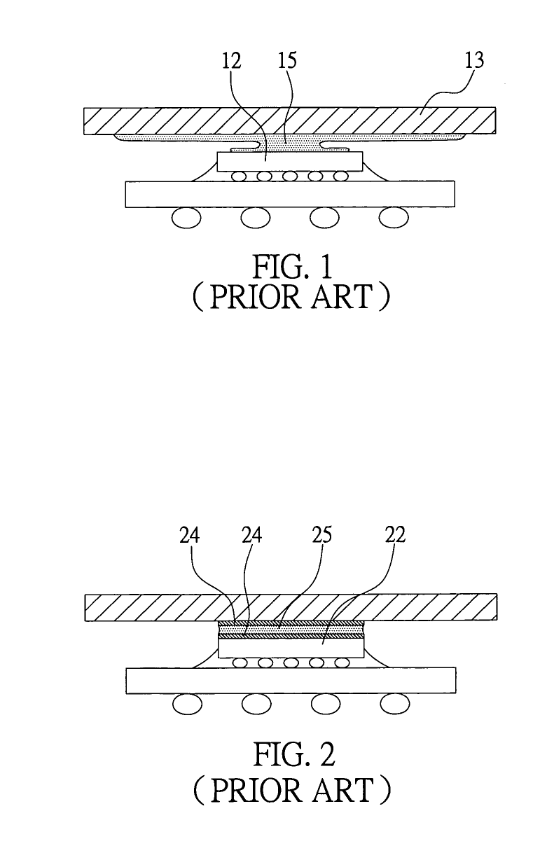

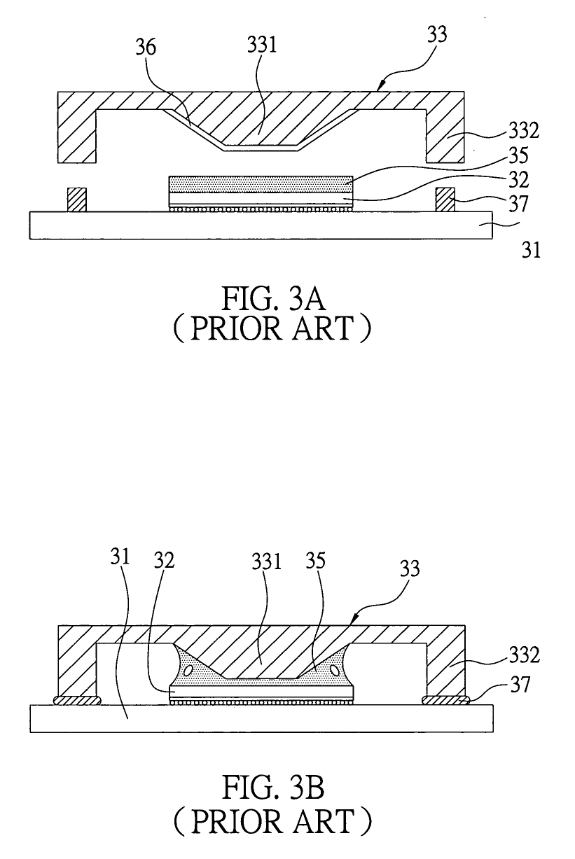

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

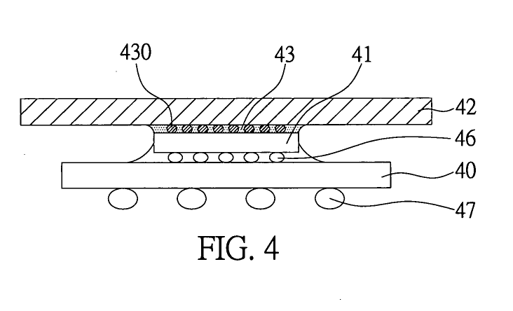

FIG. 4 is a sectional diagram of a heat dissipating semiconductor package according to the present invention.

As shown in FIG. 4, the heat dissipating semiconductor package comprises: a chip carrier 40; a semiconductor chip 41 mounted and electrically connected to the chip carrier 40; and a heat dissipating member 42 mounted on the semiconductor chip 41 with a thermal interface material (TIM) 43 interposed therebetween, wherein the TIM 43 is provided with a plurality of fillers 430 for supporting the TIM 43 at an appropriate height, thereby preventing the TIM 43 from being wetted by heat so as to avoid overflow of the TIM 43 as a result of wetting problem.

The semiconductor chip 41 is a flip-chip semiconductor chip having an active surface and a non-active surface opposed to the active surface. The chip carrier 40 is such as a BGA substrate having a first surface and a second surface opposed to the first surface. The flip-chip semiconductor chip 41 is mounted and electrically connected to the first surface of the substrate through its active surface, and a plurality of conductive bumps 46 is interposed between the active surface of the flip-chip semiconductor chip 41 and the first surface of the substrate. Meanwhile, a plurality of solder balls 47 is mounted to the second surface of the substrate such that the flip-chip semiconductor chip 41 can be electrically connected to an external device through the solder balls 47. The chip carrier 40 can also be a leadframe or a LGA substrate.

The heat dissipating member 42 can be made of a metallic material such as copper. The heat dissipating member 42 is mounted to the non-active surface of the flip-chip semiconductor chip 41 with the TIM 43 interposed therebetween. The TIM 43 may be made of such as a solder material. A plurality of fillers 430 suspends in the TIM 43, and the fillers 430 can be made of a material having high melting point such as metallic balls made of copper, aluminum or alloy thereof or other material having good rigidity and thermal conductivity such as diamond.

During mounting the heat dissipating member 42 to the semiconductor chip 41, the TIM 43 is melted into a liquid state by heat, and meanwhile, the fillers 430 in the TIM 43 at a solid state can efficiently support and form a desired thickness of TIM 43, thereby preventing the TIM 43 from being over-wetted by heat and accordingly preventing collapsing and overflow of the TIM 43 as a result of wetting problem. Furthermore, as the fillers 430 are made of a material having good thermal conductivity, heat generated by the semiconductor chip 41 during operation can be efficiently transferred to the heat dissipating member 42 through the TIM 43 and the fillers 430 therein. In addition, a metallic layer (not shown) made of such as Ni or Au can be respectively pre-disposed on opposite surfaces of the heat dissipating member 42 and the semiconductor chip 41. After the heat dissipating member 42 is disposed on the semiconductor chip 41, interposed with the TIM 43 having fillers 430, as the fillers 430 can support the TIM 43 to obtain an enough thickness, solder bonding can be formed between the metallic layers on the opposite surfaces of the heat dissipating member 42 and the flip-chip semiconductor chip 41, thereby ensuring efficient mounting of the heat dissipating member 42 to the flip-chip semiconductor chip 41 and limiting wetting area of the TIM 43. Meanwhile, by supporting the TIM 43 with the fillers 430, the TIM 43 can be controlled at an appropriate height and be prevented from being over-pressed so as to avoid overflow of the TIM 43 caused by the over-pressing problem.

Therefore, according to the heat dissipating semiconductor package of the present invention, inside a TIM used for connecting a heat dissipating member to a semiconductor chip, there is disposed a plurality of fillers such that when the TIM is melted by heat, the fillers can support the TIM at an appropriate height so as to prevent over-wetting of the TIM and thus prevent collapsing or overflow of the TIM caused by the over-wetting problem. Further, the fillers can support the TIM to obtain an enough thickness such that solder bonding can be formed between the heat dissipating member and the non-active surface of the flip-chip semiconductor chip, thereby ensuring an efficient bonding between the heat dissipating member and the flip-chip semiconductor chip. Meanwhile, compared with the complicated heat dissipating structure of the prior art, the present invention simplifies the fabrication process and saves fabrication time and cost.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A heat dissipating semiconductor package, comprising:
a chip carrier;
at least a semiconductor chip mounted and electrically connected to the chip carrier; and
a heat dissipating member mounted on the semiconductor chip with a thermal interface material (TIM) interposed therebetween, wherein the TIM is provided with a plurality of fillers for supporting the TIM at an appropriate height.

2. The heat dissipating semiconductor package of claim 1, wherein the TIM is a solder material.

3. The heat dissipating semiconductor package of claim 1, wherein the fillers are made of a material having high melting point.

4. The heat dissipating semiconductor package of claim 1, wherein the fillers are made of a thermal conductive material.

5. The heat dissipating semiconductor package of claim 1, wherein the fillers are made of one of the group consisting of copper, aluminum and alloy thereof.

6. The heat dissipating semiconductor package of claim 1, wherein the fillers are made of diamond.

7. The heat dissipating semiconductor package of claim 1, wherein the semiconductor chip is mounted on the chip carrier by flip chip technique.

8. The heat dissipating semiconductor package of claim 1, wherein the heat dissipating member is made of copper.

9. The heat dissipating semiconductor package of claim 1, wherein a metallic layer is respectively pre-formed on opposite mounting surfaces of the heat dissipating member and the semiconductor chip.

10. The heat dissipating semiconductor package of claim 9, wherein the metallic layer is made of one of the group consisting of Ni and Au.
